(19) United States
(12) Patent Application Publication
(10) Pub. No.: US 2013/0313649 A1
(43) Pub. Date: Nov. 28, 2013

(54) FIN ISOLATION FOR MULTIGATE TRANSISTORS

(71) Applicants: VEERARAGHAVAN S. BASKER, SCHENECTADY, NY (US); EFFENDI LEOBANDUNG, WAPPINGERS FALLS, NY (US); TENKO YAMASHITA, SCHENECTADY, NY (US); CHUN-CHEN YEH, CLIFTON PARK, NY (US)

(72) Inventors: VEERARAGHAVAN S. BASKER, SCHENECTADY, NY (US); EFFENDI LEOBANDUNG, WAPPINGERS FALLS, NY (US); TENKO YAMASHITA, SCHENECTADY, NY (US); CHUN-CHEN YEH, CLIFTON PARK, NY (US)

(73) Assignee: INTERNATIONAL BUSINESS MACHINES CORPORATION, ARMONK, NY (US)

(21) Appl. No.: 13/524,131

(22) Filed: Jun. 15, 2012

Related U.S. Application Data
(63) Continuation of application No. 13/478,976, filed on May 23, 2012.

(51) Int. Cl. H01L 27/088

(52) U.S. Cl. 257/368; 257/E27.06

(57) ABSTRACT

Multigate transistor devices and methods of their fabrication are disclosed. One such device includes a plurality of semiconductor fins that have source and drain regions and a gate structure overlaying the fins. The device further includes a dielectric layer that is beneath the gate structure and the fins. Here, the dielectric layer includes first dielectric regions that are disposed beneath the fins and second dielectric regions that are disposed between the fins. In addition, the first dielectric regions have a density that is greater than a density of the second dielectric regions.

### RELATED APPLICATION INFORMATION

This application is a Continuation application of co-pending U.S. patent application Ser. No. 13/478,976 filed on May 23, 2012, incorporated herein by reference in its entirety.

### BACKGROUND

1. Technical Field

The present invention relates to multigate transistors, and more particularly to isolation of fins in multigate systems, apparatuses and devices, and in methods of their fabrication.

2. Description of the Related Art

Multigate transistors, such as FinFET and Trigate devices, can be formed in a variety of ways. For example, in accordance with one class of manufacturing methods, multigate transistors can be fabricated on silicon-on-insulator (SOI) substrates. SOT substrates are advantageous, as the insulator portion of the substrate ensures electrical isolation between fins of various transistor devices constructed on the substrate. However, to save costs, multigate transistor devices are often formed on bulk semiconductor substrates. Here, to ensure isolation between fins of multigate devices, junction isolation implantation is employed, where a high-dose angled punch-through dopant is implanted at the base of the fins.

### SUMMARY

One embodiment is directed to a method for fabricating a multigate transistor device. In the method, a substrate including a semiconductor upper layer and a lower layer beneath the upper layer is provided. The lower layer has a rate of transformation into a dielectric that is higher than a rate of transformation into a dielectric of the upper layer when the upper and lower layers are subjected to dielectric transformation conditions. Fins are formed in the upper layer, and the lower layer beneath the fins is transformed into a dielectric material to electrically isolate the fins. In addition, a gate structure is formed over the fins to complete the multigate transistor device.

An alternative embodiment is directed to a method for fabricating a multigate transistor device. In accordance with the method, recesses are formed in a lower layer that is beneath a semiconductor upper layer in which fins are formed. Here, the recesses are disposed between the fins of the upper layer. Further, the recessed lower layer beneath the fins is transformed into a first dielectric material to electrically isolate the fins. In addition, a second dielectric material is deposited in the recesses and a gate structure is formed over the fins to complete the multigate transistor device.

Another embodiment is also directed to a method for fabricating a multigate transistor device. In the method, a substrate including a semiconductor upper layer and a lower layer beneath the upper layer is provided. The lower layer has a rate of transformation into a dielectric that is higher than a rate of transformation into a dielectric of the upper layer when the upper and lower layers are subjected to dielectric transformation conditions. In addition, recesses in the lower layer are formed such that the recesses are disposed between the fins of the upper layer. Further, the recessed lower layer beneath the fins is transformed into a first dielectric material to electrically isolate the fins. Additionally, a second dielectric material is deposited in the recesses and a gate structure is formed over the fins to complete the multigate transistor device.

An alternative embodiment is directed to a multigate transistor device. The device includes a plurality of semiconductor fins that have source and drain regions and a gate structure overlaying the fins. The device further includes a dielectric layer that is beneath the gate structure and the fins. Here, the dielectric layer includes first dielectric regions that are disposed beneath the fins and second dielectric regions that are disposed between the fins. In addition, the first dielectric regions have a density that is greater than a density of the second dielectric regions.

Another embodiment is directed to a multigate transistor system. The system includes a plurality of semiconductor fins that have source and drain regions and a gate structure overlaying the fins. The system further includes a dielectric layer that is beneath the gate structure and the fins. Here, the dielectric layer includes first dielectric regions that are disposed beneath the fins and second dielectric regions that are disposed between the fins. Further, the first dielectric regions have a higher resistance to wet etching than the second dielectric regions.

An additional embodiment is directed to a multigate transistor device. The device includes a plurality of semiconductor fins that have source and drain regions and a gate structure overlaying the fins. The device further includes a dielectric layer beneath the gate structure and the fins. Here, the dielectric layer includes oxidized regions that are disposed beneath the fins and deposition oxide regions that are disposed between the fins.

These and other features and advantages will become apparent from the following detailed description of illustrative embodiments thereof, which is to be read in connection with the accompanying drawings.

### BRIEF DESCRIPTION OF DRAWINGS

The disclosure will provide details in the following description of preferred embodiments with reference to the following figures wherein:

FIG. 1 is a high-level block/flow diagram of a method for fabricating a multigate device in accordance with an exemplary embodiment;

FIG. 2 is a view of a substrate comprised of a dual semiconductor layer including materials having varying degrees of rates of transformation into a dielectric in accordance with an exemplary embodiment;

FIG. 3 is a view of a multigate device structure during fabrication illustrating the formation of fins on a substrate in accordance with an exemplary embodiment;

FIG. 4 is a view of a multigate device structure during fabrication illustrating the formation of dummy spacers on fin sidewalls in accordance with an exemplary embodiment;

FIG. 5 is a view of a multigate device structure during fabrication illustrating the formation of recesses in the lower layer of the dual layer structure between the fins in accordance with an exemplary embodiment;

FIG. 6 is a view of a multigate device structure during fabrication illustrating the formation of undercuts in the lower layer of the dual layer structure beneath the sidewalls of fins in accordance with an exemplary embodiment;

FIG. 7 is a view of a multigate device structure during fabrication illustrating the transformation of the lower layer of the dual layer structure into a dielectric material in accordance with an exemplary embodiment;

FIG. 8 is a view of a multigate device structure during fabrication illustrating the deposition of dielectric material in recesses in the lower layer of the dual layer structure between fins in accordance with an exemplary embodiment;

FIG. 9 is a view of a multigate device structure during fabrication illustrating the removal of fin hard masks and of dummy spacers on the sidewalls of the fins in accordance with an exemplary embodiment;

FIG. 10 is a view of a multigate device structure during fabrication illustrating optional recessing of the deposited dielectric material that is implemented to improve electrostatic properties of channels of the multigate device in accordance with an exemplary embodiment; and

FIG. 11 is a view of a multigate device structure during fabrication illustrating the completion of the multigate device in accordance with an exemplary embodiment;

### DETAILED DESCRIPTION OF PREFERRED EMBODIMENTS

Exemplary embodiments of the present invention described herein below are directed to multigate devices fabricated on semiconductor substrates. As noted above, bulk semiconductor substrates are employed to construct multigate devices in lieu of SOI substrates due to their reduced cost. Further, as also indicated above, when a bulk silicon substrate is used, dopant implantation is performed to isolate various fins formed on the substrate. Specifically, to implement dopant junction isolation, a high-dose angled punch-through dopant is implanted at the base of the fins. However, the junction isolation implant is very difficult to control. As such, misalignment between the junction and the dielectric layer so formed would hinder device performance, similar to the effects of misalignment between spacers and channels in planar transistors.

To ensure isolation of fins of multigate devices fabricated on semiconductor substrates, embodiments of the present principles employ a semiconductor substrate that includes a dual semiconductor layer. In particular, in a preferred embodiment, the dual layer includes an upper semiconductor layer in which fins are formed and a lower semiconductor layer that has a much higher oxidation rate than the upper layer. For example, the upper layer can be composed of silicon and the lower layer can be composed of SiGe. As such, after forming recesses in the lower layer in inter-fin regions of the layer, the lower layer can be oxidized without affecting the conductive integrity of the fins due to the oxidation affinity of the lower layer. In addition, an oxide can thereafter be deposited in the recesses and a gate structure can be formed over the fins to complete the multigate device. Here, a deposition oxide can be used due to its ease of application. Further, the oxidized lower layer would have a much higher density than the deposition oxide and also a much lower wet etch rate than the deposition oxide. In contrast to the dopant junction isolation technique, the processes employed here achieve junction isolation in a very controllable way and indeed results in a self-aligned device and ensures a high degree of fin height control and fin height consistency between fins of multigate devices.

As will be appreciated by one skilled in the art, aspects of the present invention may be embodied as a system, apparatus, device or method. Aspects of the present invention are described below with reference to flowchart illustrations and/or block diagrams of methods, apparatus (systems) and devices according to embodiments of the invention. It should also be noted that, in some alternative implementations, the functions noted in the blocks may occur out of the order noted in the figures. For example, two blocks shown in succession may, in fact, be executed substantially concurrently, or the blocks may sometimes be executed in the reverse order, depending upon the functionality involved.

It is to be understood that the present invention will be described in terms of a given illustrative architecture having a substrate; however, other architectures, structures, substrate materials and process features and steps may be varied within the scope of the present invention.

It will also be understood that when an element described as a layer, region or substrate is referred to as being “on” or “over” another element, it can be directly on the other element or intervening elements may also be present. In contrast, when an element is referred to as being “directly on” or “directly over” another element, there are no intervening elements present. Similarly, it will also be understood that when an element described as a layer, region or substrate is referred to as being “beneath” or “below” another element, it can be directly beneath the other element or intervening elements may also be present. In contrast, when an element is referred to as being “directly beneath” or “directly below” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

A design for an integrated circuit chip including multigate devices of the present principles may be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer may transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein may be used in the fabrication of integrated circuit chips. The resulting integrated circuit chips can be distributed by the fabricator in raw wafer fort (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

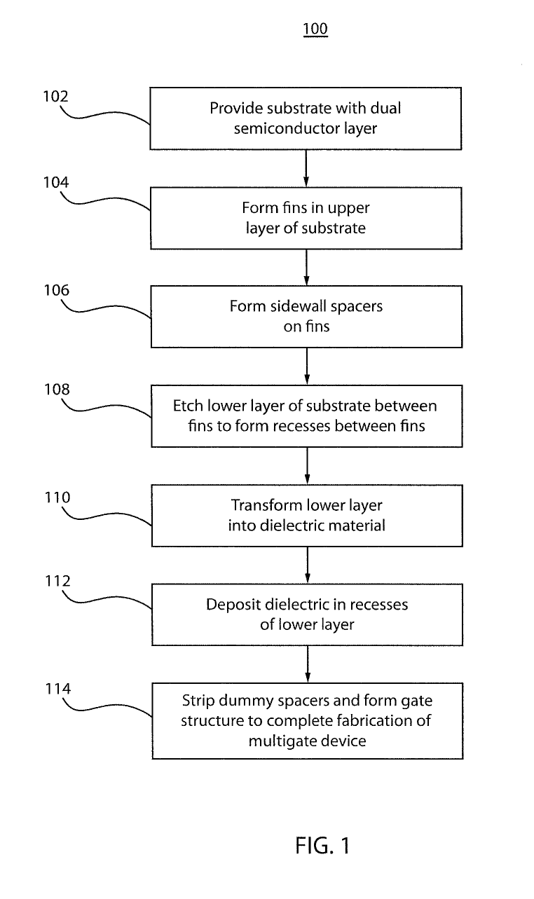

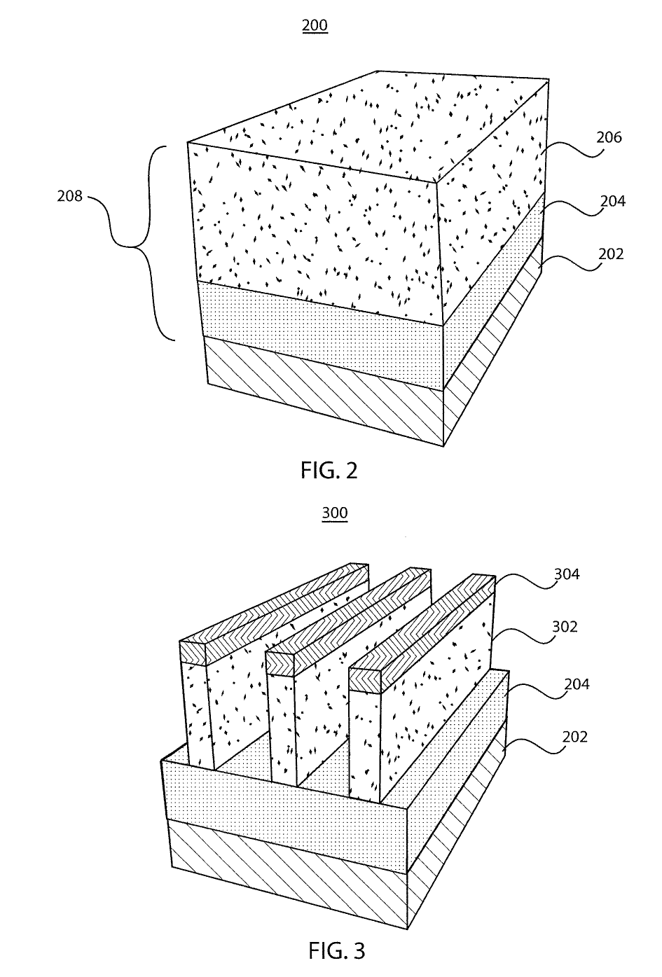

Referring now to the drawings in which like numerals represent the same or similar elements and initially to FIG. 1, a method 100 for forming a multigate device in accordance with an embodiment of the present principles is illustratively depicted. Reference is also made to FIGS. 2-11, which illustrate various processing stages in the fabrication of an exemplary multigate device in accordance with the present principles. As noted above, embodiments of the present principles are directed to multigate devices that are fabricated on a semiconductor substrate that includes a dual semiconductor layer. FIG. 2 illustrates one example of a substrate structure 200 that comprises a dual semiconductor layer 208 composed of an upper layer 206 and a lower layer 204. Materials for semiconductor upper 206 and lower layers 204 can be chosen such that the lower layer 204 has a much higher rate of transformation into a dielectric material than the upper layer 206 when subject to the same dielectric transformation conditions. For example, the upper layer 206 can be a silicon layer while the lower layer 204 can be an SiGe layer. Further, each of the upper and lower layers can be epitaxially grown on a silicon substrate, which can compose the bottom layer 202 in the structure 200. The silicon layer 202 may be a silicon layer at the surface of an SOI substrate or may be a part of a bulk silicon substrate. Where an SOI substrate is used, method 100 can be employed to isolate fins, as opposed to simply using the insulator in the SOI substrate for isolation purposes, to facilitate the fabrication of fins with a consistent, desired fin height. This is especially the case where the desired fin height is less than or substantially less than the thickness of the top silicon layer of an SOI substrate, as the etching of the silicon to achieve a relatively short desired fin height often leads to fins with inconsistent heights.

It should be noted that SiGe growth can be performed using an ultra-high-vacuum chemical vapor deposition (UHVCVD) system. This system deposits elements through vapor deposition in an ultra-high-vacuum. UHVCVD is capable of growing a wide variety of crystalline structures. In one particular example, epitaxial growth of SiGe was implemented under a mixture of Si₂H₆ and GeH₄ gas species. The base pressure of the main chamber was maintained at 106 mTorr by using a serial turbo-molecular pumping system. Thus, a very high degree of separation of the reaction chamber from the heating room was accomplished. A liquid nitrogen seal surrounding the heater suppressed out-gassing from the chamber wall and was used to cool the heater. The epitaxial growth of the SiGe layers was performed on SIMOX (Separation by Implantation of Oxygen) SOI substrates with resistivities of about 8˜12 ohm-cm. After precleaning, the samples were ready for growth and Si₂H₆ and GeH₄ gases were injected at about 600° C., and epitaxial growth was sequentially implemented within the temperature range of about 500° C.˜670 ° C.

When oxides are used for junction isolation, employing an Si/SiGe epi substrate as the layer 208 is advantageous, as the lower SiGe layer 204 here has a much higher rate of oxidation than the upper Si layer 206 when the layers are subjected oxidation conditions, as described in more detail herein below. Further, the resulting silicon dioxide permits an ease of integration with existing fabrication methods.

The method 100 can begin at step 102, at which a substrate that includes a dual semiconductor layer is provided. For example, the structure 200 of FIG. 2 can be employed as the substrate for the formation of a multigate device in accordance with the method 100. The substrate can be formed at step 102 as described above with respect to FIG. 2.

At step 104, fins for one or more multigate devices can be formed in the substrate. For example, as illustrated by structure 300 of FIG. 3, fins 302 can be formed in the upper semiconductor layer 206 and fin hard masks 304 can be formed on the fins 302 in accordance with conventional fin fabrication methods. For example, a sidewall image transfer process can be implemented to form shallow fins 302, with a height of approximately 60 nm. The reactive ion etching (RIE) can stop on the lower layer 204 to permit precise control of the heights of the fins 302.

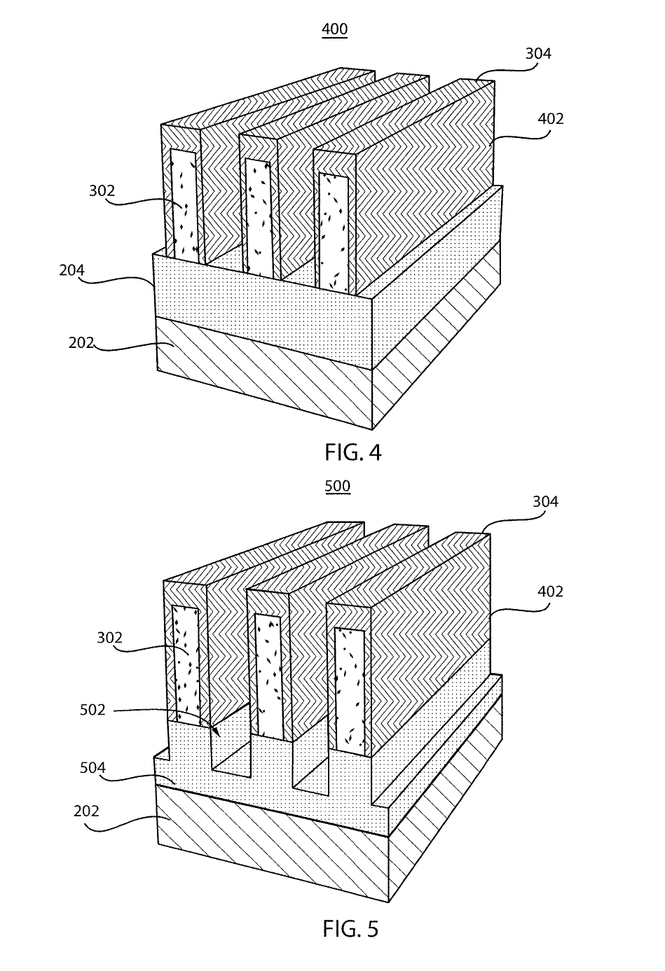

At step 106, sidewall dummy spacers can be formed on the fins. For example, sidewall dummy spacers 402 can be formed on the sidewalls of the fins 302, as illustrated by structure 400 of FIG. 4. The sidewall dummy spacers 402 can be employed to protect the fins 302 from oxidation, in an exemplary embodiment, during subsequent steps. For example, the spacers 402 can be composed of silicon nitride. For example, to faun the spacers 402, a layer of highly conformal MLD (monolayer doping) silicon nitride with thickness about 10 nm can be formed on the fins 302. Then, a high aspect ratio RIE can be conducted to pull down the spacer on the fin sidewall. As a result, portions of the layer at the top of the fin and bottom of the fin are removed.

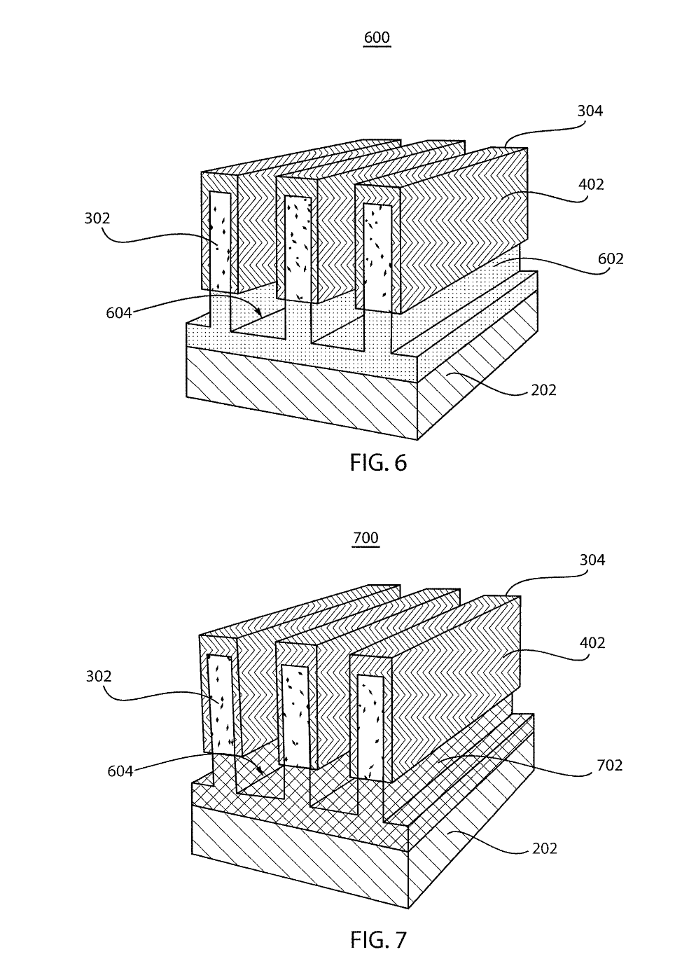

At step 108, the lower layer can be etched in regions between the fins to form recesses in the lower layer. For example, the lower layer 204 can be etched to form layer 504, which includes recesses 502 that are disposed between fins 302, as illustrated by structure 500 of FIG. 5. Here, the recesses in the lower layer are formed to expose sidewalls beneath the fins 302. In addition, wet etching can be performed in the layer 504 to undercut the fins 302 and form a resulting lower layer 602 with larger recesses 604, as illustrated by structure 600 of FIG. 6. SiGe lateral pull back can be achieved through HCl wet etching. The wet etching is selective with respect to silicon.

At step 110, the lower layer can be transformed into a dielectric material. For example, as illustrated by structure 700 of FIG. 7, the lower layer 602 can be transformed into a dielectric layer 702, which can retain the recesses 604, to electrically isolate the fins 302. As discussed above, the material for the upper and lower layers can be chosen such that the lower layer, when subjected to transformation conditions, has a much higher rate of transformation into a dielectric material than the upper layer to protect the conductive integrity of the fins 302 formed in the upper layer. For example, the lower layer 602 can be transformed into a dielectric material by oxidizing the layer. As discussed above, the materials can be chosen such that the lower semiconductor layer has a much higher oxidation rate than the upper layer.

In addition, in the example in which the lower layer is composed of SiGe, the oxidation can be implemented to transform the layer 602 into SiO₂ (with perhaps some traces of Ge) while at the same time leaving the fins 302 intact due to its oxidation properties and due to the protection from oxidation provided by the dummy sidewall spacers 402. Selective low temperature oxidation can be employed to oxidize the SiGe lower layer 702 in this example. The oxide layer 702 can be formed through Ge condensation. This technique employs oxidation of epitaxially grown SiGe on SOI substrates, where Ge atoms from SiGe are condensed into the SOI substrate. In one particular example, initial cyclic oxidation (3 cycles) was carried out at 1050° C. for three hours with an intermittent annealing time of 30 min.

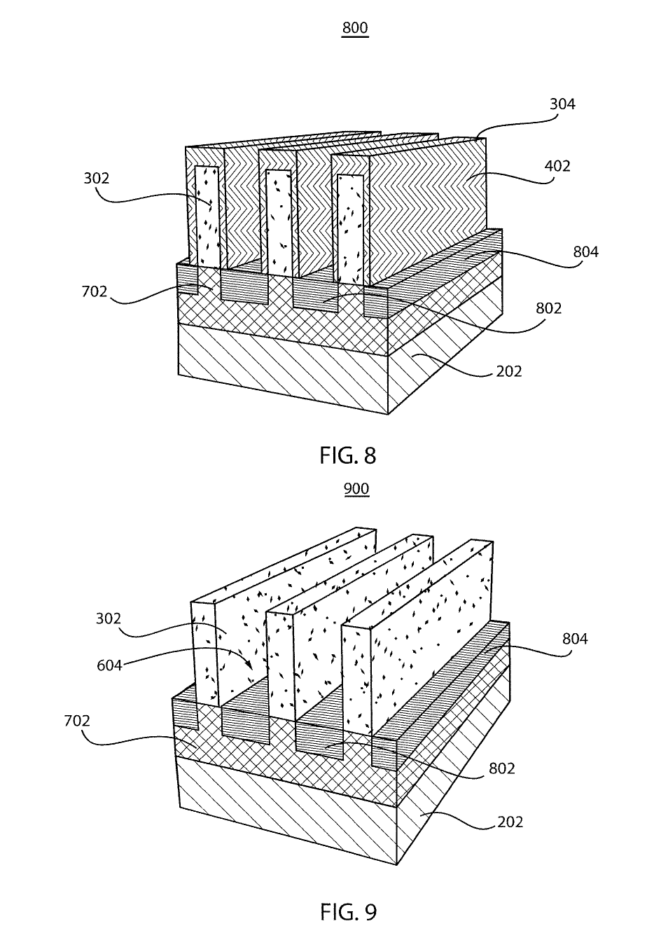

At step 112, a dielectric material can be deposited in the recesses. For example, as illustrated by structure 800 of FIG. 8, a dielectric material 802 can be deposited in the recesses 604 to form a dielectric layer 804 including the dielectric layer 702 and dielectric regions 802 disposed between the fins 302. For example, in the embodiment in which the upper layer is composed of silicon and the lower layer is composed of SiGe, the dielectric material 802 can be SiO₂. Shallow trench isolation filling and chemical mechanical planarization can be employed, followed by an oxide recess to form local shallow trench isolation zones between fins 302, thereby forming the layer 804, which is essentially composed of SiO₂. Here, in this example, the deposition oxide 802 has a significantly lower density than the oxidized layer 702 and has a substantially lower resistance to wet etching than the oxidized layer 702. As such, the regions beneath the fins 302 occupied by the layer 702 is composed of a dielectric material that has different properties than the regions 802 of dielectric material disposed between the fins 302.

At step 114, fabrication of the multigate device can be completed. For example, the dummy spacers 402 and the hard masks 304 of the fins can be stripped, as illustrated by structure 900 of FIG. 9. In accordance with one example, hot ammonia can be employed to remove the spacers 402, which may be comprised silicon nitride, as noted above. The hot ammonia is also selective with respect to silicon and oxide near the spacers.

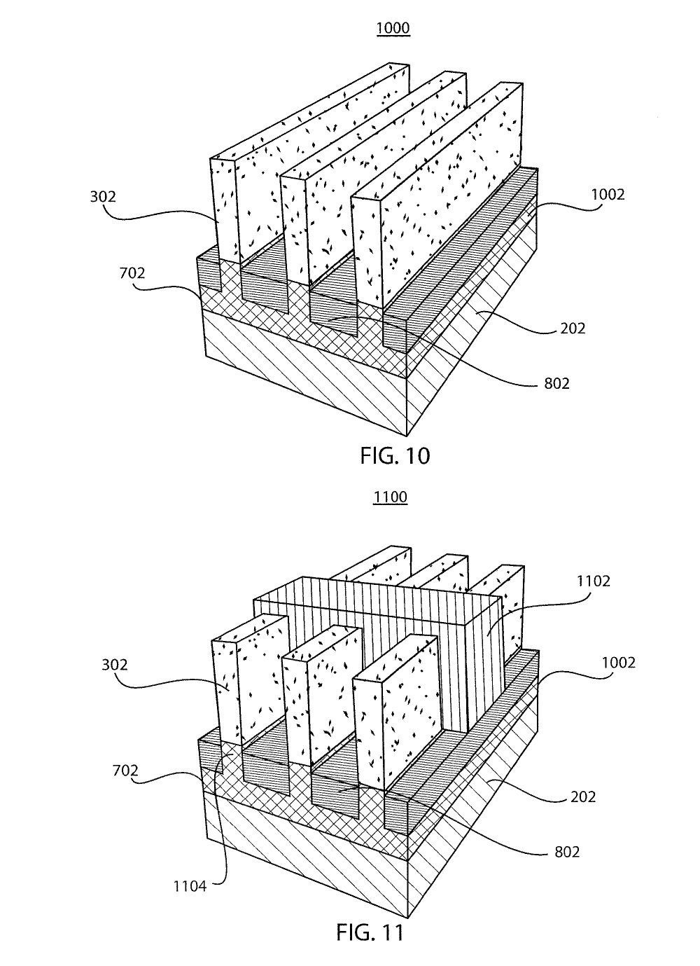

Optionally, the dielectric 802 can be recessed using any appropriate etching technique to improve electrostatic properties of the transistor device. For example, the dielectric material 802 can be etched to form layer 1002, as illustrated by structure 1000 of FIG. 10. In addition, as illustrated by structure 1100 of FIG. 11, a gate structure 1102 can be formed over the fins 302 and the multigate device can be completed in accordance with conventional methods. Further, appropriate contacts and connections can be formed to integrate the multigate device 1100 into a circuit.

With regard to the final device structure 1100 of FIG. 11, it should be noted that the fins 302 can include source and drain regions. In addition, as indicated above, the properties of the regions 1104 of the dielectric layer 1002 that are beneath the fins 302 are different than the properties of the regions 802 between the fins 302 due to the processing employed to fabricate the device. For example, as noted above, in accordance with one embodiment, the layer 702 can be formed by oxidizing silicon-germanium while the regions 802 can be formed by depositing silicon dioxide in the recesses of layer 702. As a result, the oxidized regions 1104 of the layer 702 have a density that is greater than the density of the deposition oxide regions 802. In addition, the oxidized regions 1104 of the layer 702 have a higher resistance to wet etching than the deposition oxide regions 802. Moreover, the oxidized regions 1104, and indeed the layer 702, may have traces germanium scattered throughout the regions, while the deposition oxide regions 802 are free of germanium. Furthermore, the resulting device includes a junction isolation with a perfectly controlled fin height that is on par with isolation provided by the use of an SOI substrate for the fabrication of multigate devices.

Having described preferred embodiments of multigate transistor devices and systems, and methods of their fabrication, (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A multigate transistor device comprising:
a plurality of semiconductor fins including source and drain regions;
a gate structure overlaying the fins;
a dielectric layer beneath the gate structure and the fins, wherein the dielectric layer includes first dielectric regions that are disposed beneath the fins and second dielectric regions that are disposed between the fins, wherein the first dielectric regions have a density that is greater than a density of the second dielectric regions and wherein said first dielectric regions are oxides formed by germanium condensation; and
a substrate disposed beneath the dielectric layer, said substrate including germanium atoms condensed from the dielectric layer.

2. The device of claim 1, wherein the dielectric layer is an oxide layer.

3. The device of claim 1, wherein the fins are composed of silicon.

4. The device of claim 1, wherein the dielectric layer is composed of silicon dioxide.

5. The device of claim 1, wherein the first dielectric regions include traces of germanium and wherein the second dielectric regions are free of germanium.

6. The device of claim 1, wherein top surfaces of the first dielectric regions are higher than top surfaces of the second dielectric regions.

7. The device of claim 1, wherein the first dielectric regions have a higher resistance to wet etching than the second dielectric regions.

8. A multigate transistor system comprising:
a plurality of semiconductor fins including source and drain regions;
a gate structure overlaying the fins; and
a dielectric layer beneath the gate structure and the fins, wherein the dielectric layer includes first dielectric regions that are disposed beneath the fins and second dielectric regions that are disposed between the fins, wherein the first dielectric regions have a higher resistance to wet etching than the second dielectric regions and wherein top surfaces of the first dielectric regions are higher than top surfaces of the second dielectric regions.

9. The system of claim 8, wherein the dielectric layer is an oxide layer.

10. The system of claim 8, wherein the fins are composed of silicon.

11. The system of claim 8, wherein the dielectric layer is composed of silicon dioxide.

12. The system of claim 8, wherein the first dielectric regions include traces of germanium and wherein the second dielectric regions are free of germanium.

13. (canceled)

14. The system of claim 8, wherein the first dielectric regions have a density that is greater than a density of the second dielectric regions.

15. A multigate transistor device comprising:
a plurality of semiconductor fins including source and drain regions;
a gate structure overlaying the fins; and
a dielectric layer beneath the gate structure and the fins, wherein the dielectric layer includes oxidized regions that are disposed beneath the fins and deposition oxide regions that are disposed between the fins, wherein the oxidized regions have a density that is greater than a density of the deposition oxide regions and wherein a width of a given oxidized region of said oxidized regions is at most equal to a width of the corresponding fin beneath which the given oxidized region is disposed.

16. The device of claim 15, wherein the dielectric layer is composed of silicon dioxide.

17. The device of claim 15, wherein the oxidized regions include traces of germanium and wherein the deposition oxide regions are free of germanium.

18. The device of claim 15, wherein top surfaces of the oxidized regions are higher than top surfaces of the deposition oxide regions.

19. The device of claim 15, wherein the fins are composed of silicon.

20. The device of claim 15, wherein a semiconductor layer is disposed beneath the dielectric layer.
